(19) United States
(12) Patent Application Publication
(10) Pub. No.: US 2025/0062297 A1
(43) Pub. Date: Feb. 20, 2025

(54) SEMICONDUCTOR PACKAGE

(71) Applicant: Samsung Electronics Co., Ltd., Suwon-si (KR)

(72) Inventors: Jinwon CHAE, Suwon-si (KR); Taehong MIN, Suwon-si (KR); Daehan SONG, Suwon-si (KR); Inwook JUNG, Suwon-si (KR)

(73) Assignee: Samsung Electronics Co., Ltd., Suwon-si (KR)

(21) Appl. No.: 18/678,191

(22) Filed: May 30, 2024

(30) Foreign Application Priority Data
Aug. 16, 2023 (KR) 10-2023-0106626

(51) Int. Cl. H01L 25/16; H01L 23/00; H01L 23/538; H10B 80/00

(52) U.S. Cl. CPC H01L 25/16; H01L 23/5384; H01L 24/08; H01L 24/16; H01L 24/32; H01L 24/73; H10B 80/00; H01L 2224/08145; H01L 2224/08225; H01L 2224/16145; H01L 2224/32145; H01L 2224/73204

(57) ABSTRACT

A semiconductor package may comprise an interposer substrate including a substrate and a lower protective layer, a through-via passing through the substrate and the lower protective layer, a lower pad on the lower protective layer and in contact with the through-via, an interlayer insulating layer on an upper surface of the substrate, and an interconnection structure in the interlayer insulating layer, a plurality of first semiconductor chips on an upper surface of the interposer substrate and electrically connected to the interconnection structure, a second semiconductor chip on the upper surface of the interposer substrate apart from the plurality of first semiconductor chips and electrically connected to the interconnection structure, an encapsulant covering at least a portion of the plurality of first semiconductor chips and the second semiconductor chip and connection conductors on the lower surface of the lower protective layer and electrically connected to the lower pad.

### CROSS-REFERENCE TO RELATED APPLICATION(S)

This application claims benefit of priority to Korean Patent Application No. 10-2023-0106626 filed on Aug. 16, 2023 in the Korean Intellectual Property Office, the disclosure of which is incorporated herein by reference in its entirety.

### BACKGROUND

Example embodiments of some inventive concepts relate to a semiconductor package, and to a method for manufacturing the same.

As demand for implementation of high capacitance, thinning, and miniaturization of electronic products increases, various types of semiconductor packages have been developed. Recently, in order to integrate more components (for example, semiconductor chips) into a package structure, direct bonding techniques or techniques using, for example, an adhesive film (for example, a non-conductive film (NCF)) or a connection bump (for example, a solder ball) have been developed.

### SUMMARY

Example embodiments of some inventive concepts relate to a semiconductor package having improved reliability, and a method for manufacturing the same.

According to some example embodiments of some inventive concepts, a semiconductor package may include an interposer substrate including a substrate, a lower protective layer on a lower surface of the substrate, a through-via passing through the substrate and the lower protective layer, a lower pad on a lower surface of the lower protective layer, the lower pad in contact with the through-via, an interlayer insulating layer disposed on an upper surface of the substrate, and an interconnection structure in the interlayer insulating layer, a plurality of first semiconductor chips on an upper surface of the interposer substrate, the plurality of first semiconductor chips electrically connected to the interconnection structure and stacked in a direction perpendicular to the upper surface of the interposer substrate, a second semiconductor chip on the upper surface of the interposer substrate and spaced apart from the plurality of first semiconductor chips, the second semiconductor chip electrically connected to the interconnection structure, an encapsulant on the upper surface of the interposer substrate and covering at least a portion of the plurality of first semiconductor chips and least a portion of the second semiconductor chip, and connection conductors on the lower surface of the lower protective layer, the connection conductors electrically connected to the lower pad. The plurality of first semiconductor chips may include a lowermost semiconductor chip at a lowest level and upper semiconductor chips stacked on the lowermost semiconductor chip. A thickness of the lowermost semiconductor chip may be greater than or equal to a thickness of one of the upper semiconductor chips. A width of the lowermost semiconductor chip may be the same as a width of the upper semiconductor chips.

According to example embodiments of some inventive concepts, a semiconductor package may include an interposer substrate including a substrate, an interlayer insulating layer disposed on the substrate, an upper pad on the interlayer insulating layer, and an upper insulating layer surrounding the upper pad, on the interlayer insulating layer, at least one semiconductor chip mounted on an upper surface of the interposer substrate, and an encapsulant on the upper surface of the interposer substrate and in contact with a side surface of the semiconductor chip. The semiconductor chip may include a first substrate, a first front pad below the first substrate, the first front pad in contact with the upper pad, a first front insulating layer surrounding the first front pad, the first front insulating layer in contact with at least a portion of the upper insulating layer, and a first rear insulating layer on the first substrate. A width of a portion of the upper insulating layer in contact with the first front insulating layer in a horizontal direction may be the same as a width of the first rear insulating layer in the horizontal direction.

According to example embodiments of some inventive concepts, a semiconductor package may include an interposer substrate, a plurality of first semiconductor chips on the interposer substrate, each of the plurality of first semiconductor chips having the same width in a horizontal direction, conductive bumps between the plurality of first semiconductor chips and electrically connecting the plurality of first semiconductor chips to each other, respectively, a plurality of adhesive films surrounding at least a portion of the conductive bumps, a second semiconductor chip on the interposer substrate and spaced apart from the plurality of first semiconductor chips, first and second underfill portions on the interposer substrate, the first and second underfill portions respectively covering at least a portion of the plurality of first semiconductor chips and at least a portion of the second semiconductor chip, and an encapsulant covering at least a portion of each of the plurality of first semiconductor chips and at least a portion of the second semiconductor chip.

### BRIEF DESCRIPTION OF DRAWINGS

The above and other aspects, features, and advantages of the inventive concepts will be more clearly understood from the following detailed description, taken in conjunction with the accompanying drawings, in which:

FIG. 1A is a cross-sectional view of a semiconductor package according to example embodiments of some inventive concepts, FIG. 1B is a partially enlarged view of a region corresponding to region “A” of FIG. 1A, and FIG. 1C is a partially enlarged view of a region corresponding to region “B” of FIG. 1A;

FIG. 2 is a cross-sectional view of a semiconductor package according to example embodiments of some inventive concepts;

FIG. 3 is a cross-sectional view of a semiconductor package according to example embodiments of some inventive concepts; and

FIGS. 4A to 14 are cross-sectional views and partially enlarged views of processes of a method of manufacturing a semiconductor package according to example embodiments of some inventive concepts.

### DETAILED DESCRIPTION

Hereinafter, some example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which an element or component is actually arranged.

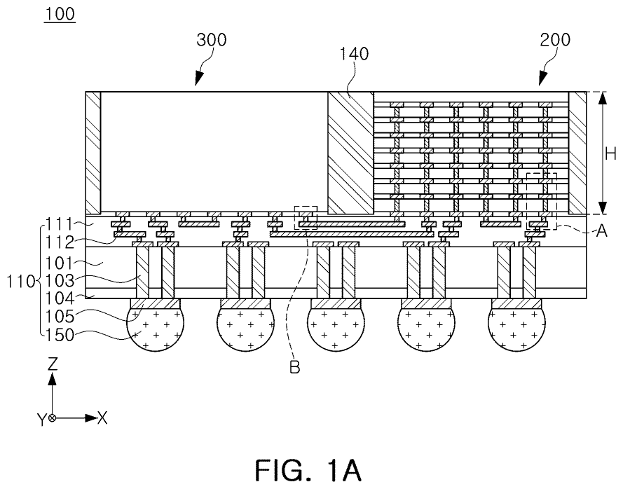

FIG. 1A is a cross-sectional view of a semiconductor package 100 according to example embodiments of some inventive concepts, FIG. 1B is a partially enlarged view of a region corresponding to region “A” of FIG. 1A, and FIG. 1C is a partially enlarged view of a region corresponding to region “B” of FIG. 1A.

Referring to FIGS. 1A, 1B, and 1C, the semiconductor package 100 according to an example embodiment may include an interposer substrate 110, a plurality of first semiconductor chips 200, a second semiconductor chip 300, an encapsulant 140, and connection conductors 150.

The interposer substrate 110, a substrate on which a plurality of semiconductor chips 200 and 300 are mounted, may include a substrate 101, a lower protective layer 104, a through-via 103, a lower pad 105, an interlayer insulating layer 111, and an interconnection structure 112. The interposer substrate 110 may further include an upper insulating layer 113 and an upper pad 115. The plurality of first semiconductor chips 200 and the second semiconductor chip 300 may be electrically connected to each other via the interposer substrate 110.

The substrate 101 may include or be formed of, for example, silicon, organic materials, plastic, and/or glass, but example embodiments are not limited thereto. When the substrate 101 includes silicon, the interposer substrate 110 may be referred to as a silicon interposer. When the substrate 101 includes organic materials, the interposer substrate 110 may be referred to as a panel interposer, but example embodiments are not limited thereto.

The lower protective layer 104 may be disposed on a lower surface of the substrate 101, and the lower pad 105 may be disposed on the lower protective layer 104.

The lower pad 105 may be connected to through-via 103. The plurality of first semiconductor chips 200 and the second semiconductor chips 300 may be electrically connected to a package substrate (not illustrated) via the connection conductors 150 disposed on the lower pad 105, but example embodiments are not limited thereto.

The interlayer insulating layer 111 may be disposed on an upper surface of the substrate 101, and the interconnection structure 112 may be disposed in the interlayer insulating layer 111. The interconnection structure 112 may, for example, have a single layer interconnection structure or a multilayer interconnection structure. When the interconnection structure 112 has a multilayer interconnection structure, interconnection patterns of different layers may be connected to each other via contact vias 112V, but example embodiments are not limited thereto.

The through-via 103 may extend through an upper surface to beyond a lower surface of the substrate 101, as to pass through the substrate 101. For example, the through-via 103 may extend into the interlayer insulating layer 111 to be electrically connected to the interconnection structure 112 disposed in the interlayer insulating layer 111. When the substrate 101 is a silicon substrate, the through-via 103 may be referred to as a through-silicon via (TSV). In some example embodiments, the interposer substrate 110 may not include a through-via.

The interposer substrate 110 may be used, for example, to convert or transmit input electrical signals between the package substrate (not illustrated) and the plurality of first semiconductor chips 200 or second semiconductor chips 300. Accordingly, the interposer substrate 110 may not include devices such as active devices or passive devices. In some example embodiments, the interlayer insulating layer 111 and the interconnection structure 112 may be disposed on a lower portion of the substrate 101.

The upper pads 115 may be disposed on an upper surface of the interlayer insulating layer 111, and the upper pads 115 may be disposed on a seed layer 114 for the upper pads 115. The seed layer 114 for the upper pads 115 may conformally extend between the upper pad 115 and the upper insulating layer 113 to surround an outer edge of the upper pad 115. The upper pad 115 and the seed layer 114 may include a conductive material. For example, the upper pad 115 may include at least one of copper (Cu), nickel (Ni), gold (Au), and silver (Ag), and the seed layer 114 may include at least one of titanium (Ti), titanium nitride (TiN), tantalum (Ta), and tantalum nitride (TaN), but example embodiments are not limited thereto.

The semiconductor package 100 according to an example embodiment may include a plurality of first semiconductor chips 200 stacked in a direction (for example, Z-axis direction), perpendicular to an upper surface of the interposer substrate 110. The plurality of first semiconductor chips 200 may include a lowermost semiconductor chip 200A disposed on a lowest level and upper semiconductor chips 200B and 200C stacked on the lowermost semiconductor chip 200A. The upper surface of the interposer substrate 110 and a lower surface of the lowermost semiconductor chip 200A may be directly bonded and/or coupled to each other (for example, such bonding and/or coupling may be include, for example, hybrid bonding, direct bonding, thermocompression bonding, or the like), without a connection member, such as a metal bump or the like, therebetween. The upper insulating layer 113 and the upper pads 115, providing the upper surface of the interposer substrate 110, may be respectively bonded and/or coupled to a first front insulating layer 213 and first front pads 215, providing the lower surface of the lowermost semiconductor chip 200A. The interposer substrate 110 may be electrically connected to the lowermost semiconductor chip 200A by bonding pad structures to which the upper pads 115 and the first front pads 215 are bonded.

The lowermost semiconductor chip 200A may include a first substrate 210, first circuit layer 211 and 212, a first front insulating layer 213, first front pads 215, a first through-electrode 216, a first rear insulating layer 217, and first rear pads 219. The lowermost semiconductor chip 200A may have a flat or substantially flat upper surface provided by an upper surface of the first rear insulating layer 217 and upper surfaces of the first rear pads 219, and may have a flat upper surface provided by a lower surface of the first front insulating layer 213 and lower surfaces of the first front pads 215.

The first substrate 210 may be a semiconductor wafer substrate having front and back surfaces opposing each other. For example, the first substrate 210 may be a semiconductor wafer including a semiconductor element such as silicon or germanium, or a compound semiconductor such as silicon carbide (SiC), gallium arsenide (GaAs), indium arsenide (InAs), and indium phosphide (InP). The front surface may be an active surface having an active region doped with impurities, and the back surface may be an inactive surface positioned to be opposite to the front surface, but example embodiments are not limited thereto.

The first circuit layer 211 and 212 may be disposed on the front surface of the first substrate 210, and may include a first interconnection structure 212 connected to the active region and a first interlayer insulating layer 211 surrounding the first interconnection structure 212. A first front pad 215, electrically connected to the first interconnection structure 212, may be disposed below the first circuit layer 211 and 212. The first front pad 215 may be a pad structure electrically connected to the first interconnection structure 212. The upper pad 115 of the interposer substrate 110 may be disposed below the first front pad 215. As described above, the first front pad 215 and the upper pad 115 may form a bonding pad structure via direct bonding, to electrically connect the interposer substrate 110 and the lowermost semiconductor chip 200A to each other.

The first interlayer insulating layer 211 may include, e.g., flowable oxide (FOX), tonen silazene (TOSZ), undoped silica glass (USG), borosilica glass (BSG), phosphosilica glass (PSG), borophosphosilica glass (BPSG), high density plasma (HDP) oxide, plasma enhanced oxide (PEOX), flowable CVD (FCVD) oxide, or any combination thereof. At least a portion of the first interlayer insulating layer 211 surrounding the first interconnection structure 212 may include or be formed of a low dielectric layer. The first interlayer insulating layer 211 may be formed using, e.g., a chemical vapor deposition (CVD) process, a flowable CVD process, or a spin coating process, but example embodiments are not limited thereto.

The first interconnection structure 212 may have a multilayer structure including an interconnection pattern and a via formed of, for example, aluminum (Al), gold (Au), cobalt (Co), copper (Cu), nickel (Ni), lead (Pb), tantalum (Ta), tellurium (Te), titanium (Ti), tungsten (W), or combinations thereof. A barrier film (not illustrated) including titanium (Ti), titanium nitride (TiN), tantalum (Ta), or tantalum nitride (TaN) may be disposed between the interconnection pattern or/and via and the first interlayer insulating layer 211. Individual devices (not illustrated) included in an integrated circuit may be disposed on a front surface of the first substrate 210. In this case, the first interconnection structure 212 may be electrically connected to the individual devices by an interconnector (not illustrated) (for example, a contact plug).

The first front insulating layer 213 may be disposed below the first substrate 210 and/or the first circuit layer 211 and 212. The first front insulating layer 213 may include an insulating material that may be bonded and/or coupled to the upper insulating layer 113 of the interposer substrate 110. For example, the first front insulating layer 213 may include silicon oxide (SiO) or silicon carbonitride (SiCN). For example, at least a portion of the first front insulating layer 213 may be bonded to the upper insulating layer 113 to form bonding surfaces for bonding and coupling the interposer substrate 110 and the lowermost semiconductor chip 200A to each other. In addition, the first front insulating layer 213 may be formed to surround a plurality of first front pads 215 arranged on a lower surface thereof.

The first through-electrode 216 may pass through the first substrate 210 to electrically connect the first front pad 215 and the first rear pad 219 to each other. The first through-electrode 216 may include a via plug (not illustrated) and a side barrier layer (not illustrated) surrounding a side surface of the via plug. The via plug may include, for example, tungsten (W), titanium (Ti), aluminum (Al), or copper (Cu), and may be formed using a plating process, PVD process, or CVD process. The side barrier layer may include titanium (Ti), titanium nitride (TiN), tantalum (Ta), or tantalum nitride (TaN), and may be formed using a plating process, a PVD process, or a CVD process. The side barrier layer may be a seed layer for forming the via plug. A side insulating film (not illustrated) including an insulating material (for example, high aspect ratio process (HARP) oxide), such as silicon oxide, silicon nitride, or silicon oxynitride, may be formed between the side barrier layer and the first substrate 210.

The first rear insulating layer 217 may be disposed on the back surface of the first substrate 210. The first rear insulating layer 217 may include an insulating layer that may be bonded and/or coupled to a second front insulating layer 223 on a lower portion of the upper semiconductor chip 200B in contact with the lowermost semiconductor chip 200A, among the upper semiconductor chips 200B and 200C. For example, the first rear insulating layer 217 may include, e.g., silicon oxide (SiO) or silicon carbonitride (SiCN). For example, at least a portion of the first rear insulating layer 217 may be bonded to the second front insulating layer 223 to form bonding surfaces for bonding and coupling between the lowermost semiconductor chip 200A and the upper semiconductor chip 200B. In addition, the first rear insulating layer 217 may be formed to surround a plurality of first rear pads 219 arranged an upper surface thereof, but example embodiments are not limited thereto.

The upper semiconductor chips 200B and 200C may be disposed on the lowermost semiconductor chip 200A, and may include a second substrate 220, second circuit layer 221 and 222, a second front insulating layer 223, and a second front pad 225. The second semiconductor chip 200 may have a flat lower surface provided by a lower surface of the second front insulating layer 223 and lower surfaces of the second front pads 225. The second front pads 225 may be bonded to the first rear pads 219 disposed on lower portion thereof to form a bonding pad structure. The lowermost semiconductor chip 200A and the upper semiconductor chips 200B and 200C may be electrically connected to each other. The lowermost semiconductor chip 200A and the upper semiconductor chips 200B and 200C may have the same, substantially the same, or similar structures, and thus the same, substantially the same, or similar components are indicated by the same or similar reference numerals, and repeated descriptions of the same components will be omitted below. For example, the second substrate 220 can be understood to have features substantially the same as those of the first substrate 210 described above.

The lowermost semiconductor chip 200A, among the plurality of first semiconductor chips 200, may be referred to, for example, as a buffer chip or a base chip. The upper semiconductor chips 200B and 200C may be stacked on the base chip 200A. A height (h1) of the base chip 200A may be equal to or greater than a height (h2) of the upper semiconductor chips 200B and 200C, but example embodiments are not limited. Among the plurality of first semiconductor chips 200, all first semiconductor chips except for the lowermost semiconductor chip 200A may have the same height, but example embodiments are not limited thereto. In an example embodiment, an uppermost first semiconductor chip 200, as compared to upper semiconductor chips 200B and 200C, may have a lower height. Furthermore, for example, a relatively thicker base chip 200A may be, for example, disposed as a lowermost semiconductor chip, among the plurality of first semiconductor chips 200 stacked in a direction (for example, Z-axis direction), perpendicular to the upper surface of the interposer substrate 110, thereby forming a more stable stack structure.

The plurality of first semiconductor chips 200 may have the same or substantially the same width in a horizontal direction (for example, X-axis direction). Each of the lowermost semiconductor chip 200A and the upper semiconductor chips 200B and 200C may have the same or substantially the same width in the horizontal direction. The plurality of first semiconductor chips 200 may be aligned to be parallel or substantially parallel to each other in a direction (for example, Z-axis direction), perpendicular to the upper surface of the interposer substrate 110, and side surfaces of the plurality of first semiconductor chips 200 may be coplanar or substantially coplanar with each other.

The plurality of first semiconductor chips 200 may include at least one memory chip including volatile memory such as dynamic RAM (DRAM) or static RAM (SRAM), and non-volatile memory such as phase change RAM (PRAM), magnetic RAM (MRAM), resistive RAM (RRAM), or flash memory, but example embodiments are not limited thereto, and may include at least one logic chip such as an analog-to-digital converter or an application-specific IC (ASIC).

The second semiconductor chip 300 may be disposed on the upper surface of the interposer substrate 110 to be spaced apart from the plurality of first semiconductor chips 200. A height (H) from the upper surface of the interposer substrate 110 to an uppermost end of the second semiconductor chip 300 may be the same as a height (H) from the upper surface of the interposer substrate 110 to an uppermost end of the plurality of first semiconductor chips 200. A height (H) of the plurality of first semiconductor chips 200 may be about 720 μm or less, but example embodiments are not limited thereto. The second semiconductor chip 300 may include front pads 315 disposed on a lower portion thereof and a front insulating layer 313 surrounding the front pads 315. The front pads 315 and the front insulating layer 313 may be bonded to the upper pads 115 and the upper insulating layer 113 of the interposer substrate 110, respectively, to form direct bonding. The second semiconductor chip 300 may include bonding the same as or similar to that of the lowermost semiconductor chip 200A, and thus repeated descriptions related thereto will be omitted.

The second semiconductor chip 300 may include a logic chip such as an analog-to-digital converter or an ASIC, but example embodiments are not limited thereto. The second semiconductor chip 300 may include, for example, a memory chip including volatile memory such as DRAM or SRAM, and non-volatile memory such as PRAM, MRAM, RRAM, or flash memory.

The encapsulant 140 may seal or at least partially seal at least a portion of each of the plurality of first semiconductor chips 200 and the second semiconductor chip 300, on the interposer substrate 110. The encapsulant 140 may fill or at least partially fill a gap between the plurality of first semiconductor chips 200 and the second semiconductor chip 300, disposed to be spaced apart from each other. The encapsulant 140 may cover or at least partially cover side surfaces of the plurality of first semiconductor chips 200 and the second semiconductor chip 300. Upper surfaces of the plurality of first semiconductor chips 200 and the second semiconductor chip 300 may be exposed from (for example, uncovered, unencapsulated, or at least partially uncovered or unencapsulated by) the encapsulant 140. A height from the upper surface of the interposer substrate 110 to an uppermost end of the encapsulant 140 may be the same as a height (H) of the plurality of first semiconductor chips 200 and the second semiconductor chip 300. The encapsulant 140 may include one or more insulating materials, for example, a thermosetting resin such as an epoxy resin, a thermoplastic resin such as polyimide, a resin in which such resins are impregnated with an inorganic filler, for example, a prepreg, Ajinomoto build-up film (ABF), FR-4, bismaleimide triazine (BT), or an epoxy molding compound (EMC), but example embodiments are not limited thereto. For example, the encapsulant 140 may include an EMC.

The connection conductors 150 may be disposed below a lower surface of the interposer substrate 110, and may be electrically connected to the lower pads 105. The connection conductors 150 may physically and/or electrically connect the semiconductor package 100 to the package substrate (not illustrated), and thus may electrically connect the semiconductor package 100 to the outside. The connection conductors 150 may include one or more conductive materials, and may individually be in the form of, for example a ball, a pin, or a lead. For example, the connection conductors 150 may include solder balls.

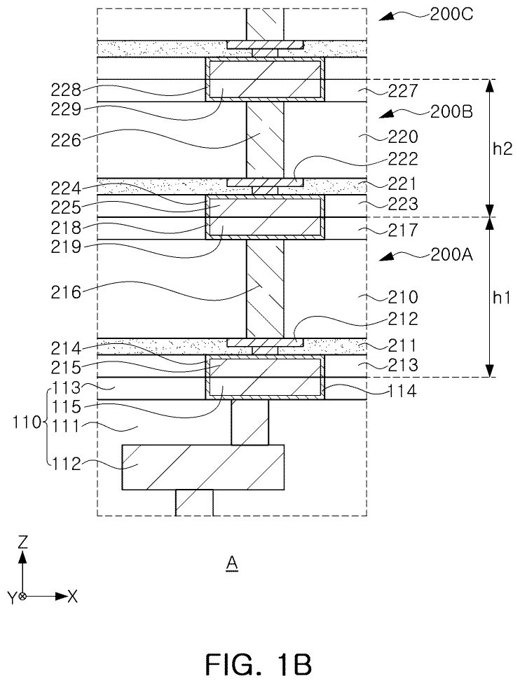

FIG. 2 is a cross-sectional view of a semiconductor package according to example embodiments of some inventive concepts.

Referring to FIG. 2, a semiconductor package 1000 according to an example embodiment may have features the same as or similar to those described with reference to FIGS. 1A to 1C, except, for example, that different types of semiconductor chips 1000A/1000B, 1000C, and 1000D are vertically stacked on an interposer substrate 110. A lowermost semiconductor chip 1000A may be bonded to the interposer substrate 110 via, for example, direct bonding. The lowermost semiconductor chip 1000A may include, for example, a logic chip such as an ASIC, but example embodiments are not limited thereto. Upper semiconductor chips 1000B, 1000C, and 1000D, stacked on the lowermost semiconductor chip 1000A, may also be bonded via direct bonding. The upper semiconductor chips 1000B, 1000C, and 1000D may include, for example, volatile memory such as DRAM or SRAM, and non-volatile memory such as PRAM, MRAM, RRAM, or flash memory, but example embodiments are not limited thereto. The upper semiconductor chips 1000B, 1000C, and 1000D may include a high bandwidth memory (HBM) structure. The lowermost semiconductor chip 1000A and the upper semiconductor chips 1000B, 1000C, and 1000D may have the same width in a horizontal direction (for example, X-axis direction). For example, a package structure including a plurality of semiconductor chips stacked in a vertical direction (for example, Z-axis direction) may be used to further reduce a package size, thereby allowing for mounting of a larger number of semiconductor chips.

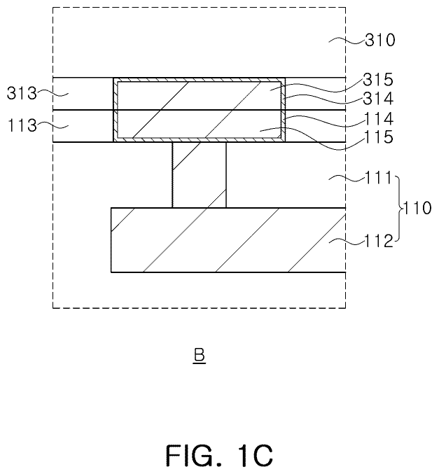

FIG. 3 is a cross-sectional view of a semiconductor package 2000 according to example embodiments of some inventive concepts.

Referring to FIG. 3, the semiconductor package 2000 according to an example embodiment may have features the same as or similar to those described with reference to FIGS. 1A to 2, except, for example, that a plurality of first semiconductor chips 200 and a second semiconductor chip 300 are respectively mounted on an interposer substrate 110 via bump structures, and a plurality of adhesive films 255 and 265 are respectively disposed between the first semiconductor chips 200. A lowermost semiconductor chip 200A may be mounted on the interposer substrate 110 via first bump structures 241 and 242. The first bump structures may include first lower mounting pads 241 and first connection bumps 242. The first lower mounting pads 241 may include, for example, at least one of aluminum (Al), copper (Cu), nickel (Ni), tungsten (W), platinum (Pt), and gold (Au), or alloys thereof, and may include at least one of a signal pad, a power pad, and a ground pad. The first connection bumps 242 may be disposed below the first lower mounting pads 241, and may be electrically connected to the lowermost semiconductor chip 200A. In some example embodiments, the first connection bumps 242 may include at least one metal pillar, at least one solder ball, or any combination thereof. The first connection bumps 242 may be connected to an interconnection structure 112 of the interposer substrate 110. A first underfill portion 240 may be disposed between the lowermost semiconductor chip 200A and the interposer substrate 110, and the first underfill portion 240 may cover at least a portion of each of the lowermost semiconductor chip 200A, the first lower mounting pads 241, and the first connection bumps 242.

The lowermost semiconductor chip 200A and an upper semiconductor chip 200B may be electrically connected to each other by conductive bumps 253 disposed therebetween. An adhesive film 255 may be disposed between the lowermost semiconductor chip 200A and the upper semiconductor chip 200B, and the adhesive film 255 may cover at least a portion of the conductive bumps 253. Conductive bumps and an adhesive film may be disposed between the plurality of first semiconductor chips 200, and repeated descriptions thereof will be omitted. Side surfaces of the plurality of adhesive films 255 and 265 may be coplanar or substantially coplanar with side surfaces of the plurality of first semiconductor chips 200, and may be in contact with the encapsulant 140. Widths of the plurality of adhesive films 255 and 265 in a horizontal direction (for example, X-axis direction) may be the same as widths of the plurality of first semiconductor chips 200 in the horizontal direction. The plurality of adhesive films 255 and 265 may include non-conductive films (NCFs), but example embodiments are not limited thereto. The plurality of adhesive films 255 and 265 may include, for example, all types of polymer films capable of a heat compression process. The plurality of adhesive films 255 and 265 may have a final structure formed by removing portions protruding further than the side surfaces of the plurality of first semiconductor chips 200, after the thermal compression process, but example embodiments are not limited thereto.

The second semiconductor chip 300 may be disposed on an upper surface of the interposer substrate 110 to be spaced apart from the plurality of first semiconductor chips 200 in the horizontal direction. A lower portion of the second semiconductor chip 300 may include second lower mounting pads 341 and second connection bumps 342, and second underfill portion 340 may be disposed between the second semiconductor chip 300 and the interposer substrate 110. The descriptions of the second lower mounting pads 341, the second connection bumps 342, and the second underfill portion 340 may be replaced with the above descriptions of the first lower mounting pads 241, the first connection bumps 242, and the first underfill portion 240. E.g., a plurality of adhesive films having the same width in the horizontal direction may be applied, such that the adhesive films are not exposed to the outside of an encapsulant, thereby reducing or preventing exterior defects and improving reliability of a semiconductor package.

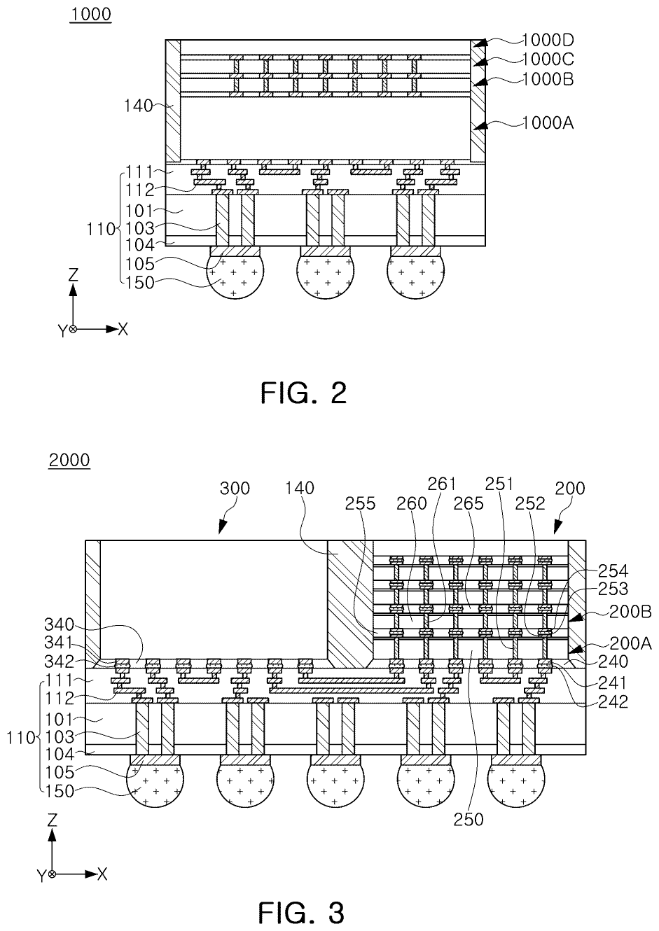

Hereinafter, an example method of manufacturing the semiconductor package 100 illustrated in FIGS. 1A to 1C will be described with reference to FIGS. 4A to 14.

FIGS. 4A to 14 are cross-sectional views and partially enlarged views of processes of a method of manufacturing a semiconductor package according to example embodiments of some inventive concepts.

Referring to FIGS. 4A and 4B, an interposer substrate 110, including a substrate 101, an interlayer insulating layer 111, an interconnection structure 112, and a through-via 103, may be prepared.

The interconnection structure 112 may be disposed in the interlayer insulating layer 111. The interconnection structure 112, disposed at different levels, may be electrically connected via a contact via 112V. A portion of the interlayer insulating layer 111 may be removed, such that an upper surface of the contact via 112V, disposed on a highest level, may be formed to be exposed from the interlayer insulating layer 111.

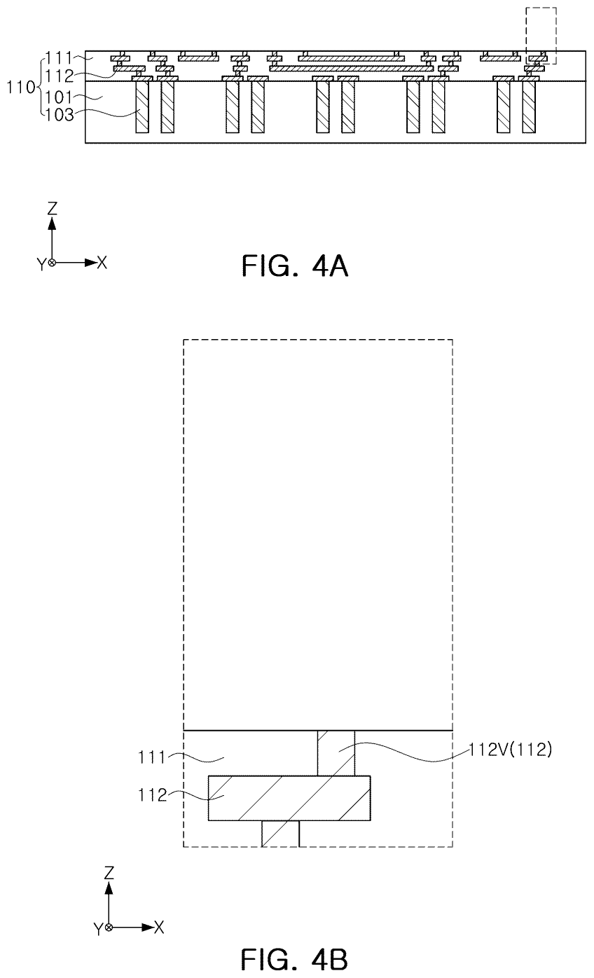

Referring to FIGS. 5A and 5B, an upper insulating layer 113 defining a first recessed region RC1 may be formed on an upper surface of the interlayer insulating layer 111.

The first recessed region RC1 may be formed by etching at least a portion of a preliminary insulating layer formed on the interlayer insulating layer 111. The preliminary insulating layer may include, for example, silicon oxide (SiO) and/or silicon carbonitride (SiCN), and may be formed using a PVD or CVD process. For example, the first recessed region RC1 may be formed using an etching process such as reactive-ion etching (RIE) using photoresist (not illustrated).

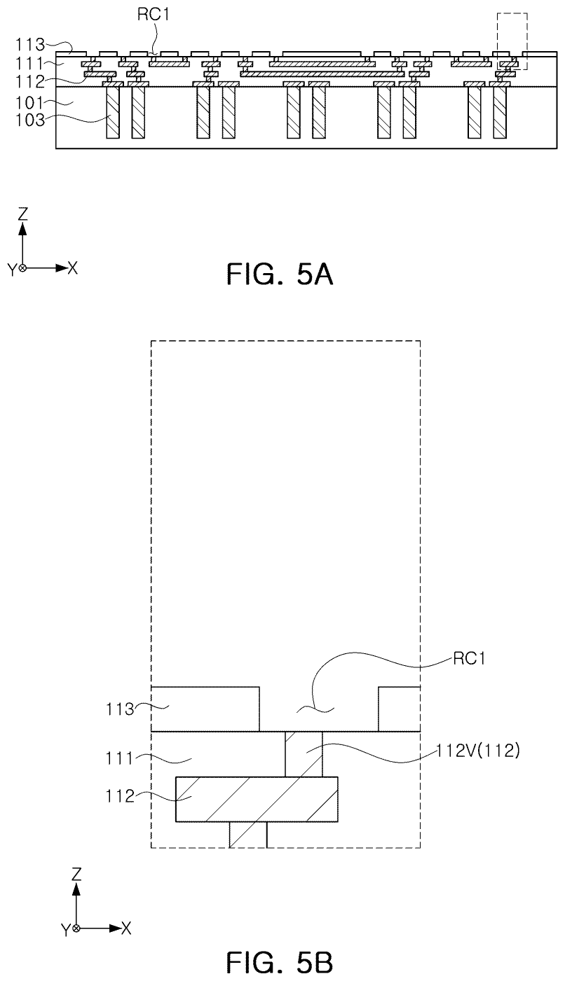

Referring to FIGS. 6A and 6B, a preliminary seed layer 114p and a preliminary upper pad 115p may be formed on a surface of the upper insulating layer 113 and in the first recessed region RC1.

The preliminary seed layer 114p may be formed conformally along the surface of the upper insulating layer 113. The preliminary upper pad 115p may be formed on the preliminary seed layer 114p and may fill the first recessed region RC1. The preliminary seed layer 114p and the preliminary upper pad 115p may be formed using, for example, a plating process, a PVD process, or a CVD process. For example, the preliminary seed layer 114p may include at least titanium (Ti) or titanium nitride (TiN), and the preliminary upper pad 115p may include at least copper (Cu), but example embodiments are not limited thereto.

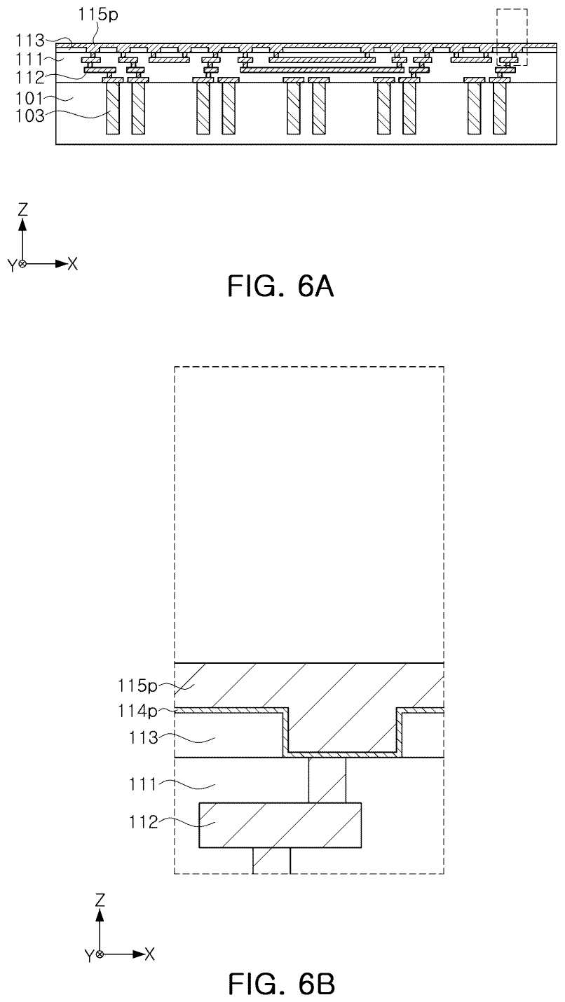

Referring to FIGS. 7A and 7B, the preliminary seed layer 114p and the preliminary upper pad 115p may be polished to form a seed layer 114, for an upper pad, and an upper pad 115.

A portion of the preliminary seed layer 114p and the preliminary upper pad 115p may be removed using a polishing process, and the seed layer 114, for an upper pad, and the upper pad 115 may be formed. The polishing process may be performed, for example, using a CMP process using a first slurry. The first slurry may have polishing selectivity for the preliminary seed layer 114p, the preliminary upper pad 115p, and the upper insulating layer 113. For example, an upper surface of the upper pad 115 may be formed to have a shape depressed relative to an upper surface of the upper insulating layer 113 that may be relatively flattened using the polishing process. Such a relatively depressed shape may provide expansion space for a subsequent process of bonding the upper pad 115.

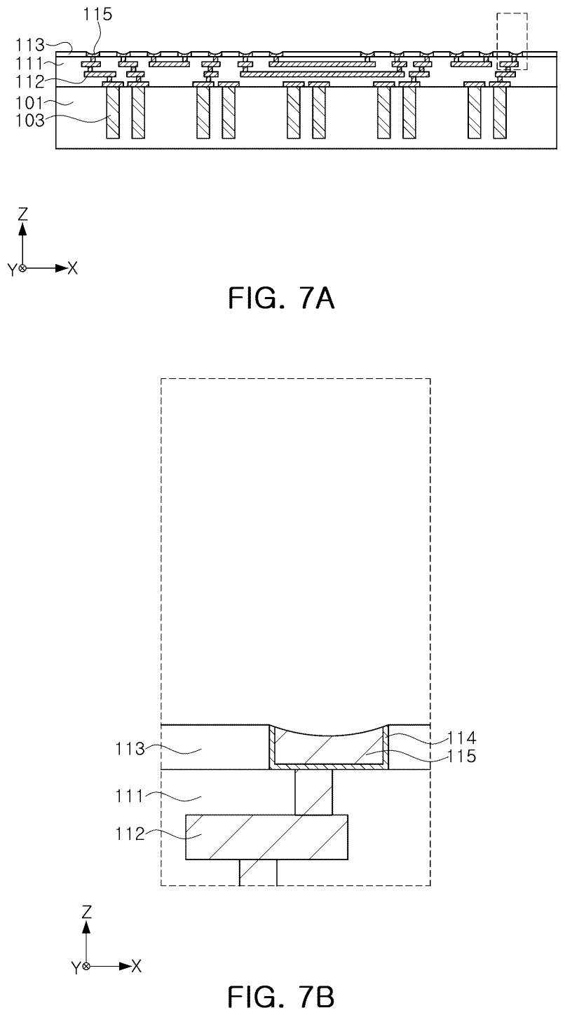

Referring to FIGS. 8A and 8B, a first front insulating layer 213 including a second recessed region RC2 may be formed on a lowermost semiconductor chip 200A.

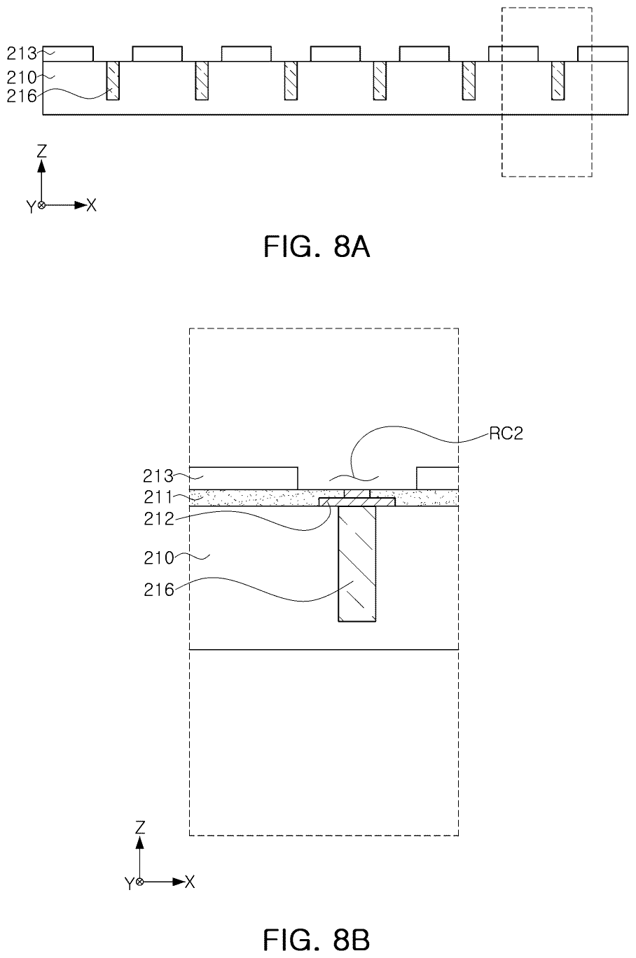

The lowermost semiconductor chip 200A may include a first substrate 210, first circuit layer 211 and 212 disposed on a front surface of the first substrate 210, and a first front insulating layer 213 disposed on the first circuit layer 211 and 212. For ease of understanding, the lowermost semiconductor chip 200A is illustrated in FIGS. 8A to 9B as being rotated or inverted to a form that is a mirror image of the structure illustrated in FIGS. 1A to 1C, for ease of understanding. The second recessed region RC2 may be formed by etching at least a portion of a preliminary insulating layer formed on the first circuit layer 211 and 212. The preliminary insulating layer may include, for example, silicon oxide (SiO) and/or silicon carbonitride (SiCN), and may be, for example, formed using a PVD or CVD process, but example embodiments are not limited thereto. For example, the second recessed region RC2 may be formed using an etching process such as RIE using photoresist (not illustrated).

Referring to FIGS. 9A and 9B, a seed layer 214, for a first front pad, and a first front pad 215 may be formed.

A preliminary seed layer (not illustrated) may be formed conformally along a surface of the first front insulating layer 213. A first preliminary front pad (not illustrated) may be formed on the preliminary seed layer and may fill the second recessed region RC2. The preliminary seed layer and the first preliminary front pad may be formed using, e.g., a plating process, a PVD process, or a CVD process, but example embodiments are not limited thereto. A portion of the first preliminary front pad and the preliminary seed layer may be removed using a polishing process, and the first front pad 215 and the seed layer 214 for the first front pad may be formed. The polishing process may be performed, for example, using a CMP process using a first slurry. For example, an upper surface of the first front pad 215 may be formed to have a depressed shape relative to an upper surface of the first front insulating layer 213 that may be relatively flattened using the polishing process. Such a relatively depressed shape may provide expansion space for a subsequent process of bonding the first front pad 215.

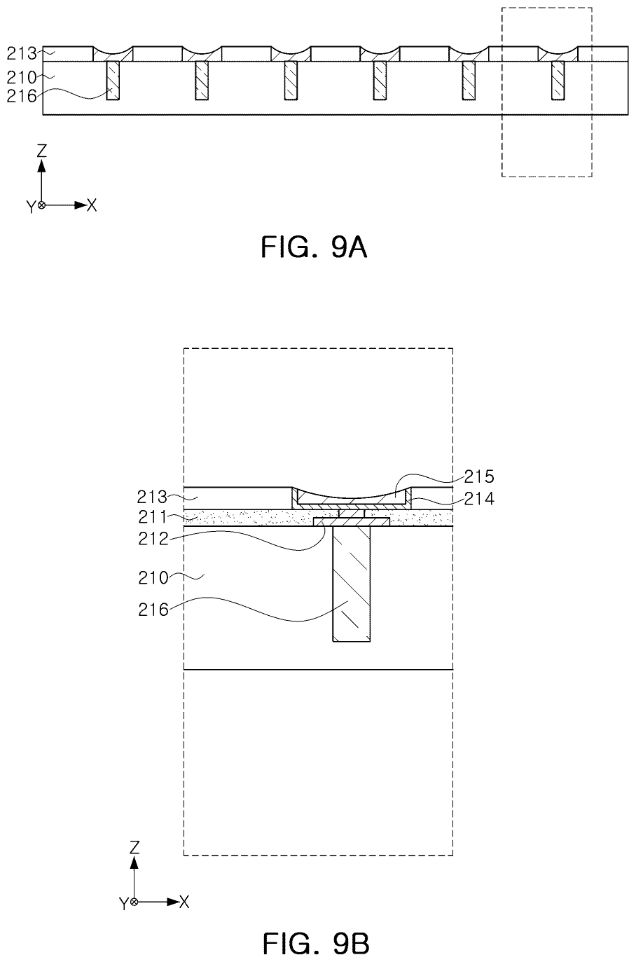

Referring to FIGS. 10A and 10B, the lowermost semiconductor chip 200A may be bonded onto the interposer substrate 110.

Through example embodiments shown in FIGS. 4A to 9B, the interposer substrate 110 and the lowermost semiconductor chip 200A may be prepared. The interposer substrate 110 and the lowermost semiconductor chip 200A may or may not be sequentially prepared, and may be formed using independent manufacturing processes.

Subsequently, the lowermost semiconductor chip 200A may be disposed on the interposer substrate 110. The lowermost semiconductor chip 200A may be aligned on the interposer substrate 110 using, for example, a pick-and-place device. The upper pads 115 may be aligned and disposed to be in contact with the first front pads 215, and the upper insulating layer 113 may be aligned and disposed to be in contact with the first front insulating layer 213.

Subsequently, a thermal compression process may be performed to couple, to each other, the upper insulating layer 113 and the first front insulating layer 213 bonded to each other, and to couple, to each other, a plurality of upper pads 115 and a plurality of first front pads 215 bonded to each other. The heat compression process may be performed such that the upper insulating layer 113 and the first front insulating layer 213 are first bonded to each other, and then the plurality of upper pads 115 and the plurality of first front pads 215 are bonded to each other.

A first through-electrode 216 of the lowermost semiconductor chip 200A may be disposed on the first substrate 210, and may not be exposed from the first substrate 210.

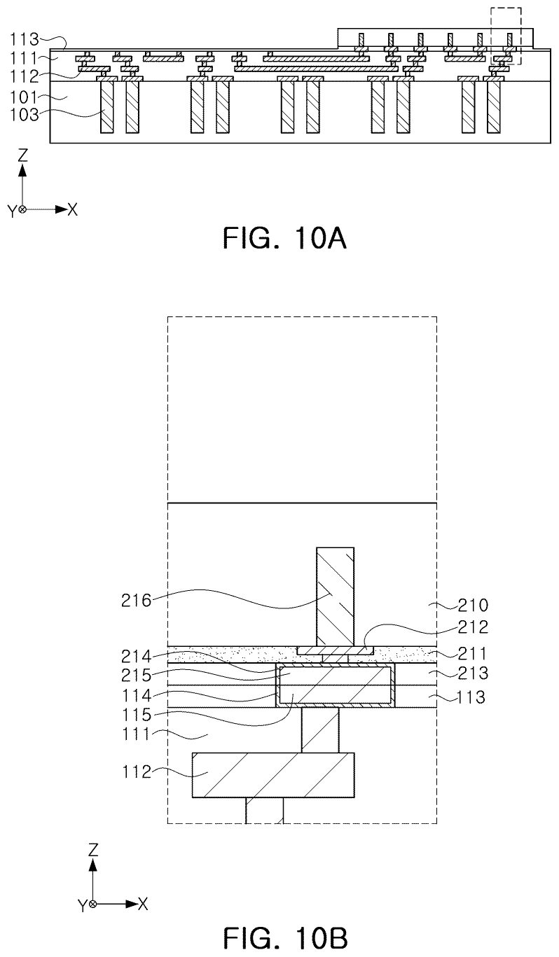

Referring to FIGS. 11A and 11B, an upper semiconductor chip 200B may be bonded to the lowermost semiconductor chip 200A.

A portion of the first substrate 210 may be removed such that an upper surface of the first through-electrode 216 of the lowermost semiconductor chip 200A is exposed from the first substrate 210. A first rear pad 219 and a first rear insulating layer 217 surrounding the first rear pad 219 may be formed on the first substrate 210 from which a portion is removed. A series of processes for forming the first rear pad 219 and the first rear insulating layer 217 may have features the same as or similar to those of a process of forming the upper pad 215 and the upper insulating layer 213 or a process of forming the first front pad 215 and the first front insulating layer 213. Thus, repeated descriptions related thereto will be omitted.

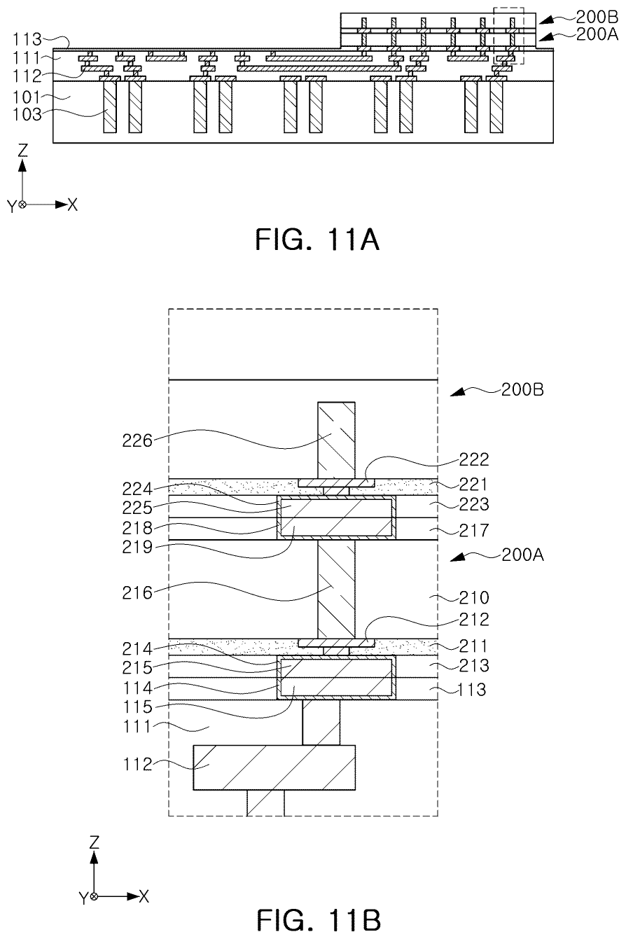

Referring to FIG. 12, a plurality of first semiconductor chips 200 may all be bonded onto the interposer substrate 110.

A process of bonding the plurality of first semiconductor chips 200 to each other may be performed by repeatedly performing the series of processes described with reference to FIGS. 10A to 11B. A height (H) at which the plurality of first semiconductor chips 200 are mounted may be about 720 μm or less, but example embodiments are not limited thereto. In the semiconductor package 100 according to an example embodiment, the height (H) of the plurality of first semiconductor chips 200 may have a high degree of freedom, as compared to a case in which a standardized HBM structure is formed and mounted.

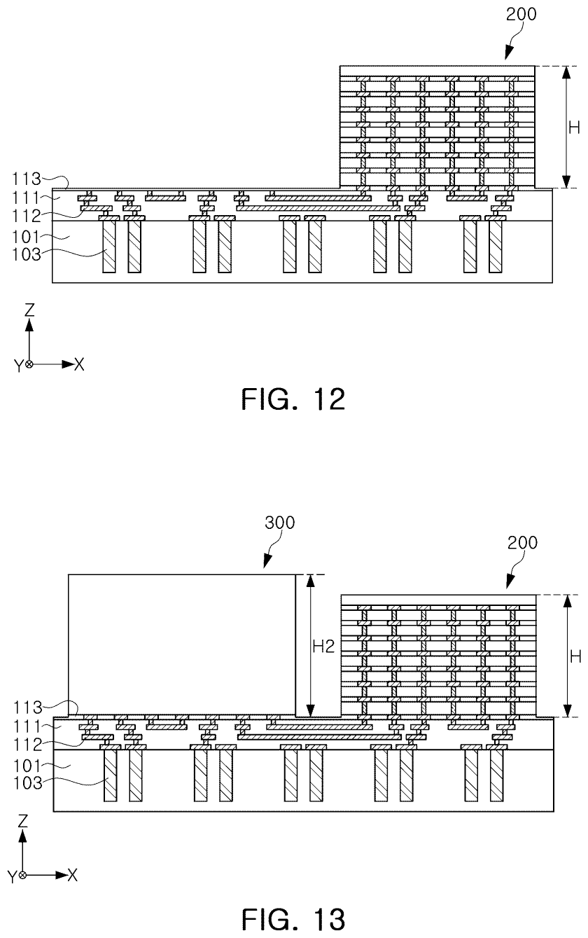

Referring to FIG. 13, a second semiconductor chip 300 may be bonded to the interposer substrate 110, and may be disposed to be spaced apart from the plurality of first semiconductor chips 200.

The height (H2) at which the second semiconductor chip 300 is mounted may be higher than the height (H) at which a plurality of first semiconductor chips are mounted, but example embodiments are not limited thereto. A lower portion of the second semiconductor chip 300 may include front pads 315 and a front insulating layer 313 surrounding the front pads 315 (as shown in, for examples, FIG. 1C), and may be bonded, for example via direct bonding, to the upper pads 115 and the upper insulating layer 113 disposed in a series of regions spaced apart from the plurality of first semiconductor chips 200. Such a bonding process may be the same as, substantially the same as, or similar to the process of bonding the lowermost semiconductor chip 200A described with reference to FIGS. 10A and 10B, and thus repeated descriptions related thereto will be omitted. The second semiconductor chip 300 may be a logic chip such as an analog-to-digital converter or an ASIC, but example embodiments are not limited thereto.

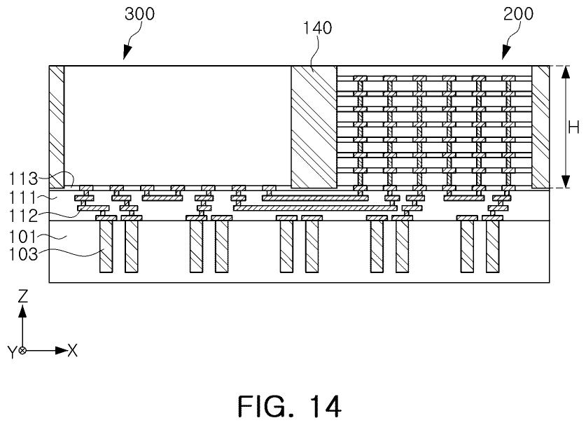

Referring to FIG. 14, an encapsulant 140 may be formed by providing (for example, depositing or filling a space with) an encapsulating material on the interposer substrate 110 and grinding a portion thereof.

The encapsulating material may be provided to cover at least a portion of the plurality of first semiconductor chips 200 and the second semiconductor chip 300. A portion of the encapsulating material may cover or cover at least partially cover upper surfaces of the plurality of first semiconductor chips 200. A grinding process may be performed to remove encapsulating material and a portion of the second semiconductor chip 300 above the height (H) of the plurality of first semiconductor chips 200, and then a planarization process such as CMP may be performed to form the encapsulant 140. An uppermost end of the encapsulant 140 may be positioned on a level the same as that of uppermost ends of the plurality of first semiconductor chips 200 and the second semiconductor chip 300, and upper surfaces of the plurality of first semiconductor chips 200 and the second semiconductor chip 300 may be exposed from the encapsulant 140, but example embodiments are not limited thereto.

Subsequently, referring to FIGS. 1A to 1C together, a portion of the substrate 101 may be removed to expose a lower surface of the through-via 103. Thereafter, lower pads 105 may be disposed on a lower surface of the substrate 101 so as to be in contact with the lower surface of the through-via 103, and connection conductors 150 may be attached onto the lower pads 105. The connection conductors 150 may include, for example, a combination of a metal pillar and a solder ball, and may then be connected to an external device (for example, motherboard) via a package substrate. As a result, the semiconductor package 100 of FIGS. 1A to 1C may be manufactured.

According to example embodiments of some inventive concepts, a semiconductor package may have a structure in which a plurality of semiconductor chips all having the same width in a horizontal direction are stacked in a vertical direction, and thus may have improved reliability.

While example embodiments have been shown and described above, it will be apparent to those ordinarily skilled in the art that modifications and variations could be made without departing from the spirt and scope of the inventive concepts as in the appended claims.

Although example embodiments of inventive concepts have been described with reference to the accompanying drawings, it will be apparent to those skilled in the art that inventive concepts may be realized in various forms without being limited to the above-described example embodiments and may be embodied in other specific forms without departing from the technical spirit and essential characteristics. Thus, the above example embodiments are to be considered in all respects as illustrative and neither limiting nor restrictive.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

What is claimed is:

1. A semiconductor package, comprising:
an interposer substrate including a substrate, a lower protective layer on a lower surface of the substrate, a through-via passing through the substrate and the lower protective layer, a lower pad on a lower surface of the lower protective layer, the lower pad in contact with the through-via, an interlayer insulating layer on an upper surface of the substrate, and an interconnection structure in the interlayer insulating layer;
a plurality of first semiconductor chips on an upper surface of the interposer substrate, the plurality of first semiconductor chips electrically connected to the interconnection structure and stacked in a direction perpendicular to the upper surface of the interposer substrate;
a second semiconductor chip on the upper surface of the interposer substrate and apart from the plurality of first semiconductor chips, the second semiconductor chip electrically connected to the interconnection structure;
an encapsulant on the upper surface of the interposer substrate, the encapsulant covering at least a portion of the plurality of first semiconductor chips and at least a portion of the second semiconductor chip, respectively; and
connection conductors on the lower surface of the lower protective layer, the connection conductors electrically connected to the lower pad,
wherein the plurality of first semiconductor chips includes
a lowermost semiconductor chip at a lowest level and
upper semiconductor chips stacked on the lowermost semiconductor chip,
a thickness of the lowermost semiconductor chip is greater than or equal to a thickness of one of the upper semiconductor chips, and
a width of the lowermost semiconductor chip is same as a width of the upper semiconductor chips.

2. The semiconductor package of claim 1, wherein uppermost ends of the plurality of first semiconductor chips are coplanar with an uppermost end of the second semiconductor chip.

3. The semiconductor package of claim 2, wherein an uppermost end of the encapsulant is positioned on a level same as that of the uppermost ends of the plurality of first semiconductor chips and the second semiconductor chip.

4. The semiconductor package of claim 1, wherein each of the upper semiconductor chips have same thickness.

5. The semiconductor package of claim 1, wherein the plurality of first semiconductor chips includes at least one memory chip.

6. The semiconductor package of claim 1, wherein the second semiconductor chip includes a logic chip.

7. The semiconductor package of claim 1, wherein a distance from the upper surface of the interposer substrate to uppermost ends of the plurality of first semiconductor chips is 720 μm or less.

8. The semiconductor package of claim 1, wherein the lowermost semiconductor chip further includes a first substrate, a first circuit layer below the first substrate, a first front pad below the first circuit layer, a first rear pad on the first substrate, and a first through-electrode passing through the first substrate to electrically connect the first rear pad and the first front pad to each other.

9. The semiconductor package of claim 1, wherein upper surfaces of the plurality of first semiconductor chips and upper surfaces of the second semiconductor chip are exposed from the encapsulant.

10. The semiconductor package of claim 1, wherein the plurality of first semiconductor chips are aligned in the direction perpendicular to the upper surface of the interposer substrate.

11. A semiconductor package, comprising:
an interposer substrate including a substrate, an interlayer insulating layer on the substrate, an upper pad on the interlayer insulating layer, and an upper insulating layer on the interlayer insulating layer and surrounding the upper pad;
at least one semiconductor chip on an upper surface of the interposer substrate; and
an encapsulant on the upper surface of the interposer substrate and in contact with a side surface of the semiconductor chip,
wherein the semiconductor chip includes a first substrate, a first front pad below the first substrate, the first front pad in contact with the upper pad, a first front insulating layer surrounding the first front pad, the first front insulating layer in contact with at least a portion of the upper insulating layer, and a first rear insulating layer on the first substrate, and
a width of a portion of the upper insulating layer in contact with the first front insulating layer in a horizontal direction is same as a width of the first rear insulating layer in the horizontal direction.

12. The semiconductor package of claim 11, wherein the at least one semiconductor chip includes a plurality of semiconductor chips stacked in a direction perpendicular to the upper surface of the interposer substrate.

13. The semiconductor package of claim 12, wherein each of the plurality of semiconductor chips have a same width in the horizontal direction.

14. The semiconductor package of claim 13, wherein the plurality of semiconductor chips includes a logic chip at a lowest level.

15. A semiconductor package comprising:
an interposer substrate;
a plurality of first semiconductor chips on the interposer substrate, each of the plurality of first semiconductor chips having a same width in a horizontal direction;
conductive bumps between the plurality of first semiconductor chips and electrically connecting each of the plurality of first semiconductor chips to each other;
a plurality of adhesive films surrounding at least a portion of the conductive bumps;
a second semiconductor chip on the interposer substrate and spaced apart from the plurality of first semiconductor chips;
first and second underfill portions on the interposer substrate, the first and second underfill portions respectively covering at least a portion of the plurality of first semiconductor chips and at least a portion of the second semiconductor chip; and
an encapsulant covering at least a portion of each of the plurality of first semiconductor chips and at least a portion of the second semiconductor chip.

16. The semiconductor package of claim 15, wherein widths of the plurality of adhesive films in the horizontal direction are same as widths of the plurality of first semiconductor chips in the horizontal direction.

17. The semiconductor package of claim 15, wherein each of the plurality of adhesive films have a same width in the horizontal direction.

18. The semiconductor package of claim 15, wherein side surfaces of the plurality of adhesive films are in contact with the encapsulant.

19. The semiconductor package of claim 15, wherein the plurality of adhesive films are apart from each other in a vertical direction.

20. The semiconductor package of claim 15, wherein side surfaces of the conductive bumps are in contact with the plurality of adhesive films.
